(19) United States
(12) Patent Application Publication
(10) Pub. No.: US 2025/0351342 A1
(43) Pub. Date: Nov. 13, 2025

(54) SEMICONDUCTOR DEVICE AND MANUFACTURING METHOD THEREOF

(71) Applicant: SK hynix Inc., Icheon-si Gyeonggi-do (KR)

(72) Inventor: Hyeok Jun CHOI, Icheon-si Gyeonggi-do (KR)

(73) Assignee: SK hynix Inc., Icheon-si Gyeonggi-do (KR)

(21) Appl. No.: 18/949,715

(22) Filed: Nov. 15, 2024

(30) Foreign Application Priority Data
May 7, 2024 (KR) 10-2024-0059748

(51) Int. Cl. H10B 41/30; H01L 23/528; H01L 23/532; H10B 43/30

(52) U.S. Cl. CPC H10B 41/30; H01L 23/5283; H01L 23/53295; H10B 43/30

(57) ABSTRACT

There are provided a semiconductor device and a manufacturing method thereof. The semiconductor device includes: a gate stack structure including a plurality of interlayer insulating layers and a plurality of conductive layers, which are alternately stacked in a third direction; a channel plug formed in a cell region, the channel plug penetrating the gate stack structure in the third direction; and at least one support structure formed in a contact region, the channel plug penetrating the gate stack structure in the third direction. The support structure includes a plurality of support structure layers that are sequentially stacked in the third direction, and the plurality of support structure layers are sequentially disposed such that each of the plurality of support structure layers extends in different directions along a plane defined by a first direction and a second direction, the first direction, the second direction, and the third direction being orthogonal to each other.

### CROSS-REFERENCE TO RELATED APPLICATION

The present application claims priority under 35 U.S.C. § 119(a) to Korean patent application number 10-2024-0059748 filed on May 7, 2024, in the Korean Intellectual Property Office, the entire contents of which application is incorporated herein by reference.

### BACKGROUND

### 1. Technical Field

The present disclosure generally relates to an electronic device, and more particularly, to a semiconductor device and a manufacturing method thereof.

### 2. Related Art

A nonvolatile memory device is a memory device in which stored data is retained even when the supply of power is interrupted. As the improvement of the degree of integration of two-dimensional nonvolatile memory devices in which memory cells are formed in the form of a single layer over a substrate reaches its limit, there has recently been proposed a three-dimensional nonvolatile memory device in which memory cells are stacked vertically over a substrate.

The three-dimensional nonvolatile memory device includes interlayer insulating layers and gate electrodes, which are alternately stacked, and channel layers penetrating the interlayer insulating layers and the gate electrodes, and memory cells are stacked along the channel layers. Various structures and various manufacturing methods have been developed so as to improve the operational reliability of such a nonvolatile memory device having a three-dimensional structure.

### SUMMARY

In accordance with an aspect of the present disclosure, there is provided a semiconductor device including: a gate stack structure including a plurality of interlayer insulating layers and a plurality of conductive layers, which are alternately stacked in a third direction; a channel plug formed in a cell region, the channel plug penetrating the gate stack structure in the third direction; and at least one support structure formed in a contact region, the at least one support structure penetrating the gate stack structure in the third direction, wherein the support structure includes a plurality of support structure layers that are sequentially stacked in the third direction, and the plurality of support structure layers are sequentially disposed such that each of the plurality of support structure layers extends in different directions along a plane defined by a first direction and a second direction, the first direction, the second direction, and the third direction being orthogonal to each other.

In accordance with another aspect of the present disclosure, there is provided a semiconductor device including: a buffer layer, extending in a plane defined by a first direction and a second direction, including a plurality of first buffer layers and a plurality of second buffer layers, which are alternately stacked in a third direction; a gate stack structure including a plurality of interlayer insulating layers and a plurality of conductive layers, which are alternately stacked on the buffer layer; and a channel plug formed in a cell region and penetrating the gate stack structure in the third direction, the first direction, the second direction, and the third direction being orthogonal to each other.

In accordance with still another aspect of the present disclosure, there is provided a method of manufacturing a semiconductor device, the method including: forming a first stack structure, extending in a plane defined by a first direction and a second direction, in which a plurality of first interlayer insulating layers and a plurality of first sacrificial layers are alternately stacked in a third direction on a substrate, the first stack structure including a cell region and a contact region, wherein the first direction, the second direction, and the third direction are orthogonal to each other; forming a first support structure penetrating the first stack structure on the contact region, wherein the first support structure is formed to extend in the first direction; forming, on the first stack structure, a second stack structure in which a plurality of second interlayer insulating layers and a plurality of second sacrificial layers are alternately stacked; forming a second support structure in the contact region, the second support structure having a portion overlapping with the first support structure and penetrating the second stack structure, wherein the second support structure is formed to extend in a direction that is rotated at a certain angle with respect to the first direction; forming, on the second stack structure, a third stack structure in which a plurality of third interlayer insulating layers and a plurality of third sacrificial layers are alternately stacked; and forming a third support structure in the contact region, the third support structure having a portion overlapping with the second support structure and penetrating the third stack structure, wherein the third support structure is formed to extend in a direction that is rotated at a certain angle with respect to the extending direction of the second support structure.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIGS. 1A and 1B are block diagrams schematically illustrating semiconductor devices in accordance with embodiments of the present disclosure.

FIG. 2 is a sectional view schematically illustrating a peripheral circuit structure.

FIGS. 3A and 3B are plan and sectional views illustrating a semiconductor device in accordance with an embodiment of the present disclosure.

FIGS. 4A and 4B are plan and perspective views illustrating a support structure in accordance with an embodiment of the present disclosure.

FIGS. 5 and 6 are perspective views illustrating a support structure in accordance with another embodiment of the present disclosure.

FIGS. 7, 8A, 8B, 9A, 9B, 10A, 10B, 11A, 11B, 12, and 13 are sectional and plan views illustrating a manufacturing method of the semiconductor device in accordance with an embodiment of the present disclosure.

FIG. 14 is a view illustrating memory blocks included in the semiconductor memory device in accordance with an embodiment of the present disclosure.

FIG. 15 is a block diagram illustrating a configuration of a memory system in accordance with an embodiment of the present disclosure.

FIG. 16 is a block diagram illustrating a configuration of a memory system in accordance with an embodiment of the present disclosure.

FIG. 17 is a block diagram illustrating a configuration of a computing system in accordance with an embodiment of the present disclosure.

FIG. 18 is a block diagram illustrating a configuration of a computing system in accordance with an embodiment of the present disclosure.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Hereinafter, exemplary embodiments of the present disclosure will be described in detail with reference to the accompanying drawings in order for those skilled in the art to be able to readily implement the technical spirit of the present disclosure.

Embodiments provide a semiconductor device having a stable structure and improved characteristics, and a manufacturing method of the semiconductor device.

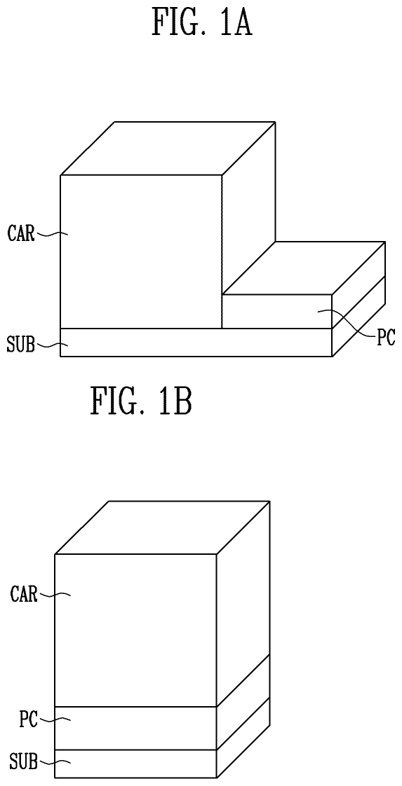

FIGS. 1A and 1B are block diagrams schematically illustrating semiconductor devices in accordance with embodiments of the present disclosure.

Referring to FIGS. 1A and 1B, each of the semiconductor devices in accordance with the embodiments of the present disclosure may include a peripheral circuit structure PC and a cell array CAR, which are disposed on a substrate SUB.

The substrate SUB may be a single crystalline semiconductor layer. For example, the substrate SUB may be a bulk silicon substrate, a silicon on insulator substrate, a germanium substrate, a germanium on insulator substrate, a silicon-germanium substrate, or an epitaxial thin film formed through a selective epitaxial growth process.

The cell array CAR may include a plurality of memory blocks. Each of the memory blocks may include a plurality of cell strings. Each of the cell strings may be electrically connected to a bit line, a source line, word lines, and select lines. Each of the cell strings may include memory cells and select transistors, which are connected in series. Each of the select lines may be used as an agate electrode of a select transistor corresponding thereto, and each of the word lines may be used as a gate electrode of a memory cell corresponding thereto.

The peripheral circuit structure PC may include NMOS and PMOS transistors, a resistor, and a capacitor, which are electrically connected to the cell array CAR. The NMOS and PMOS transistors, the resistor, and the capacitor may be used as elements constituting a row decoder, a column decoder, a page buffer, and a control circuit.

As shown in FIG. 1A, the peripheral circuit structure PC may be disposed on a partial region of the substrate SUB, the partial region not overlapping with the cell array CAR.

Alternatively, as shown in FIG. 1B, the peripheral circuit structure PC may be disposed between the cell array CAR and the substrate SUB. The peripheral circuit structure PC may overlap with the cell array CAR, and hence, an area of the substrate SUB occupied by the cell array CAR and the peripheral circuit structure PC can be reduced.

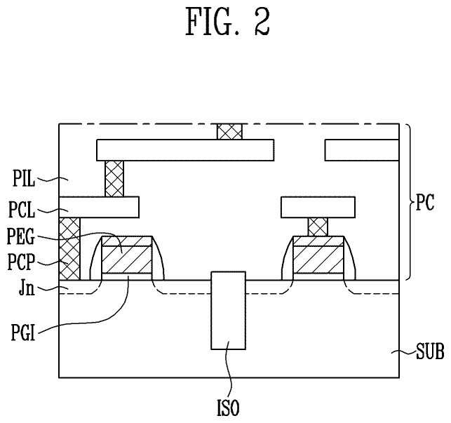

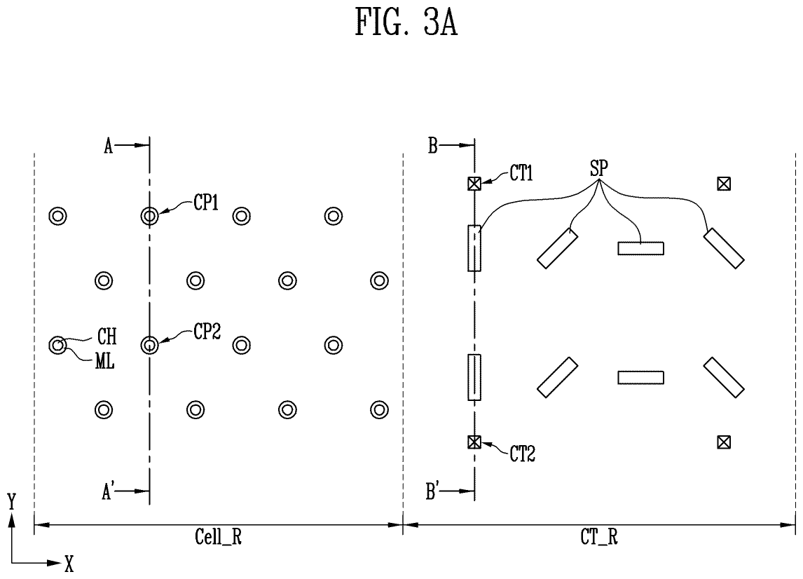

FIG. 2 is a sectional view schematically illustrating a peripheral circuit structure.

The peripheral circuit structure PC, shown in FIG. 2, may be included in the peripheral circuit structure, shown in FIG. 1A, or may be included in the peripheral circuit structure, shown in FIG. 1B.

Referring to FIG. 2, the peripheral circuit structure PC may include peripheral gate electrodes PEG, a peripheral gate insulating layer PGI, junctions Jn, peripheral circuit lines PCL, and peripheral contact plugs PCP. A peripheral circuit insulating layer PIL, formed on the substrate SUB, may fill areas around the peripheral circuit structure PC.

Each of the peripheral gate electrodes PEG may be used as a gate electrode of each of the NMOS and PMOS transistors of the peripheral circuit structure PC. The peripheral gate insulating layer PGI may be disposed between each of the peripheral gate electrodes PEG and the substrate SUB.

The junctions Jn may be regions defined by implanting an n-type or p-type impurity into an active region of the substrate SUB. The junctions Jn may be disposed at both sides of each of the peripheral gate electrodes PEG to be used as source and drain junctions. The active region of the substrate SUB may be partitioned by an isolation layer ISO formed inside the substrate SUB. The isolation layer ISO may be formed of an insulating material.

The peripheral circuit lines PCL may be electrically connected to transistors, a resistor, and a capacitor through the peripheral contact plugs PCP. The transistors, the resistor, and the capacitor may constitute a circuit of the peripheral circuit structure PC.

The peripheral circuit insulating layer PIL may include insulating layers stacked in a multi-layer structure.

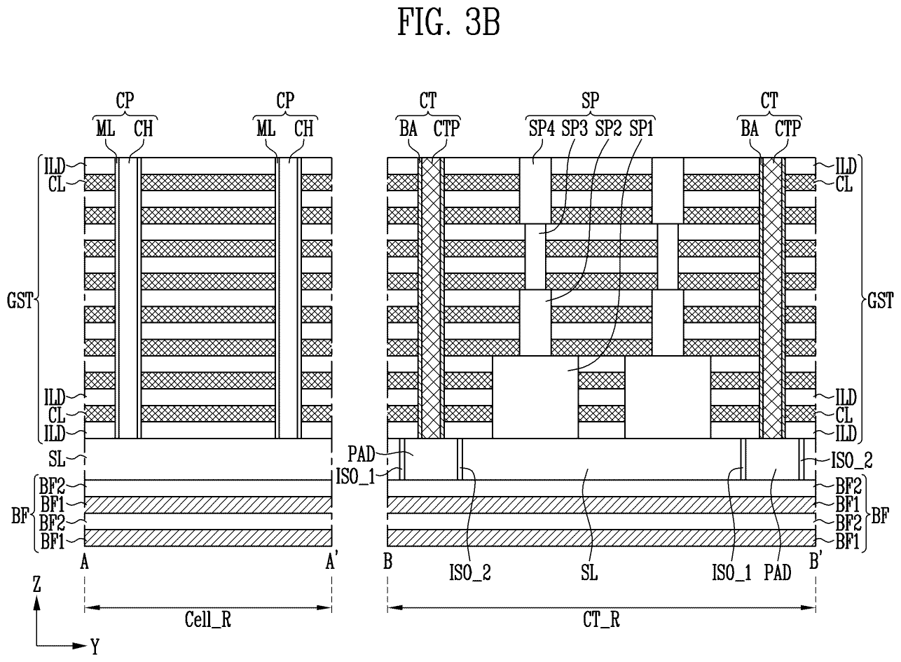

FIGS. 3A and 3B are plan and sectional views illustrating a semiconductor device in accordance with an embodiment of the present disclosure.

Referring to FIG. 3A, a cell array (CAR shown in FIGS. 1A and 1B) of the semiconductor device may include a cell region Cell_R and a contact region CT_R. A plurality of channel plugs CP1 and CP2 may be regularly arranged in the cell region Cell_R. Each of the plurality of channel plugs CP1 and CP2 may include a channel layer CH and a memory layer ML, the memory layer ML surrounding the channel layer CH.

A plurality of contacts CT1 and CT2 may be regularly arranged on the contact region CT_R. In addition, at least one support structure SP may be arranged on the contact region CT_R. The support structure SP may be an insulating layer, and may be formed of, for example, an oxide layer. The support structure SP may be formed to have several sectional shapes. For example, the support structure SP may have a cross-section of a bar shape as shown in the drawing. In another embodiment, the support structure SP may have a T-type, a Y-type, circular, or polygonal cross-section. The support structures SP having the cross-section of the bar shape may extend in different directions in the same level layer. For example, some support structures SP in the same level layer may extend in a first horizontal direction X, some support structure SP in the same level layer may extend in a second horizontal direction Y that is orthogonal to the first horizontal direction X, and some support structures SP in the same level layer may extend in a diagonal direction in relation to the first horizontal direction X and the second horizontal direction Y.

Referring to FIG. 3B, section A-A′ may be a section of the cell region Cell_R, and section B-B′ may be a section of the contact region CT_R. A buffer layer BF, a source line layer SL stacked on the buffer

layer BF, a gate stack structure GST stacked on the source line layer SL, and channel plugs CP in contact with the source line layer SL while penetrating the gate stack structure GST in a vertical direction Z may be formed in the cell region Cell_R of the semiconductor device.

The buffer layer BF may include at least one first buffer layer BF1 and at least one second buffer layer BF2, and the first buffer layer BF1 and the second buffer layer BF2 may be alternately stacked.

For example, the first buffer layer BF1 may include a metal material, and the second buffer layer BF2 may include rubber or oxide. A vertical displacement and a horizontal displacement, which are caused by stress, may be reduced by the first buffer layer BF1 and the second buffer layer BF2, which are alternately stacked. For example, the vertical displacement may be reduced by the first buffer layer BF1 that includes a metal material, and the horizontal displacement may be reduced by the second buffer layer BF2, the second buffer layer BF2 having high elasticity as compared with the first buffer layer BF1. Because the buffer layer BF includes a plurality of first buffer layers BF1 and a plurality of second buffer layers BF2, stress in a horizontal direction in a structure under the buffer layer BF can be suppressed from being transferred to the gate stack structure GST disposed above the buffer layer BF.

The source line layer SL may be a doped semiconductor layer. For example, the source line layer SL may be a semiconductor layer doped with an n-type impurity.

The gate stack structure GST may have a structure in which a plurality of conductive layers CL and a plurality of interlayer insulating layers ILD are alternately stacked. A lowermost end and an uppermost end of the gate stack structure GST may have a structure in which an interlayer insulating layer ILD is disposed. At least one conductive layer disposed at a lowermost end, among the plurality of conductive layers CL, may be a source select line, at least one conductive layer disposed at an uppermost end, among the plurality of conductive layers CL, may be a drain select line, and the rest of the conductive layers may be word lines.

The channel plugs CP may be vertically arranged and may penetrate the gate stack structure GST. Each of the channel plugs CP may include a channel layer CH and a memory layer ML, the memory layer ML surrounding the channel layer CH.

A buffer layer BF, a source line layer SL, isolation layers ISO_1 and ISO2, and a contact pad layer PAD, a gate stack structure GST, contacts CT in contact with the contact pad layer PAD and penetrating the gate stack structure GST in the vertical direction Z, and at least one support structure SP in contact with the source line layer SL and penetrating the gate stack structure GST in the vertical direction Z. The source line layer SL, isolation layers ISO_1 and ISO2, and the contact pad layer PAD may be stacked on the buffer layer BF. The gate stack structure may be stacked on the source line layer SL, the isolation layers ISO_1 and ISO2, and the contact pad layer PAD.

The source line layer SL and the contact pad layer PAD may be formed on the same layer. The source line layer SL and the contact pad layer PAD may be electrically isolated from each other by the isolation layers ISO_1 and ISO_2 that are disposed between the source line layer SL and the contact pad layer PAD. The isolation layers ISO_1 and ISO_2 may be formed of an insulating layer. For example, the isolation layers ISO_1 and ISO_2 may be formed of an oxide layer. The contact pad layer PAD may be electrically connected to the peripheral circuit structure PC, shown in FIGS. 1A and 1B.

Each of the contacts CT may include a contact plug CTP and a barrier layer BA surrounding the contact plug CTP.

The support structure SP may include a plurality of support structure layers SP1, SP2, SP3, and SP4. Each of the plurality of support structure layers SP1, SP2, SP3, and SP4 may be formed on the same layer as at least one pair of a conductive layer and an interlayer insulating layer.

The support structure SP may have a screw shape, a twist shape, or a spiral step shape. For example, each of the plurality of support structure layers SP1, SP2, SP3, and SP4 may extend, on an X-Y plane, in a direction that is different from a direction in which an adjacent support structure layer extends, the adjacent support structure layer being adjacent in the vertical direction Z. Each of the plurality of support structure layers SP1, SP2, SP3, and SP4 may form radial lines extending through a common center. For example, a first support structure layer SP1 may be disposed to extend in the second horizontal direction Y, a second support structure layer SP2 disposed on the first support structure layer SP1, in the vertical direction Z, may be disposed to extend in a direction having a certain angle (greater than 0 and less than 90 degrees) from the second horizontal direction Y, the third support structure layer SP3 disposed on the second support structure layer SP2, in the vertical direction Z, may extend in a horizontal direction that is orthogonal to the second horizontal direction Y, and the fourth support structure SP4 disposed on the third support structure layer SP3, in the vertical direction Z, may extend in a direction that is orthogonal to the direction in which the second support structure layer SP2 extends.

The plurality of support structure layers SP1, SP2, SP3, and SP4 included in the support structure SP may be arranged such that the extending direction of each of the plurality of support structure layers SP1, SP2, SP3, and SP4 is rotated clockwise or counterclockwise. Thus, stress occurring in the gate stack structure GST can be reduced while being distributed in several directions.

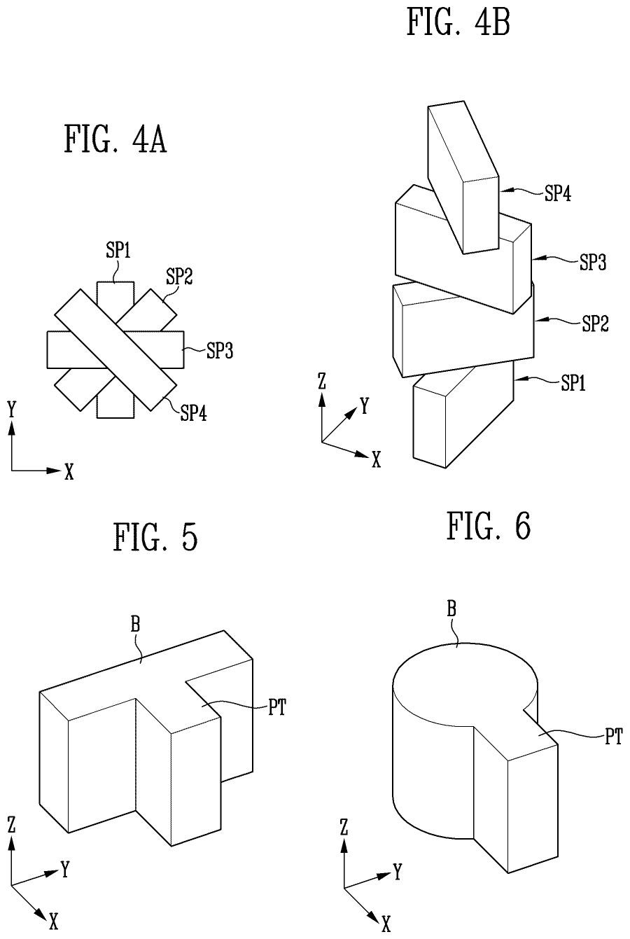

FIGS. 4A and 4B are plan and perspective views illustrating a support structure in accordance with an embodiment of the present disclosure.

Referring to FIGS. 4A and 4B, a plurality of support structure layers SP1, SP2, SP3, and SP4 may have bar shapes extending in different directions.

For example, a first support structure layer SP1, disposed at a lowermost portion in the vertical direction Z, may extend in the second horizontal direction Y, and a second support structure SP2, disposed on the first support structure layer SP1 in the vertical direction Z, may extend in a first diagonal direction that is between the first horizontal direction X and the second horizontal direction Y. For example, the extending direction of the second support structure layer SP2 may be a direction that is based on the second support structure layer SP2 rotated along the X-Y plane, when assuming that the middle of the second support structure layer SP2 is pinned along the Z axis, at a certain angle with respect to the extending direction of the first support structure layer SP1. In addition, a third support structure layer SP3 disposed on the second support structure layer SP2 may extend in the first horizontal direction X, and the extending direction of the third support structure layer SP3 may be a direction that is based on the third support structure layer SP3 rotating along the X-Y plane, when assuming that the middle of the third support structure layer SP3 is pinned along the Z axis, at a certain angle with respect to the extending direction of the second support structure layer SP2. In addition, the fourth support structure layer SP4 disposed on the third support structure layer SP3 may extend in a second diagonal direction that is between the first horizontal direction X and the second horizontal direction Y, and the extending direction of the fourth support structure layer SP4 may be based on the fourth support structure layer SP4 rotated along the X-Y plane, when assuming that the middle of the fourth support structure layer SP4 is pinned along the Z axis, at a certain angle with respect to the extending direction of the third support structure layer SP3.

As described above, the plurality of support structure layers SP1, SP2, SP3, and SP4 having bar shapes may be stacked while rotated each layer by progressively increasing angles when assuming that the middle of the support structure layers are pinned along the Z axis, to form a screw shape, a twist shape, or a spiral step shape.

In the above-described embodiment, four support structure layers are illustrated and described. However, the present disclosure is not limited thereto, and at least two support structure layers may be stacked to constitute the support structure.

FIGS. 5 and 6 are perspective views illustrating a support structure in accordance with another embodiment of the present disclosure.

In FIGS. 4A and 4B described above, it has been described that one support structure layer has a bar shape. However, the present disclosure is not limited thereto. For example, each support structure layer may have a T shape as shown in FIG. 5. Referring to FIG. 5, the support structure layer may include a body portion B having a bar shape and a protrusion portion PT protruding in one direction from a central portion of the body portion B.

In the support structure in which each of a plurality of support structure layers has a T shape, the plurality of support structure layers may be stacked such that an extending direction of a body portion B and an extending direction of a protrusion portion PT for each support structure layer are different from extending directions of body portions B and extending directions of protrusion portions PT for a top support structure layer and a bottom support structure layer in the vertical direction Z.

Referring to FIG. 6, each support structure layer may include a body portion having a cylindrical structure and a protrusion portion PT protruding in one direction from the body portion B.

In the support structure in which each of a plurality of support structure layers has a body portion B having a cylindrical structure and a protrusion portion PT, body portions B of the support structure layers may be disposed to overlap with each other in the vertical direction Z, and protrusion portions PT of the support structure layers may be disposed to not overlap with each other in the vertical direction Z.

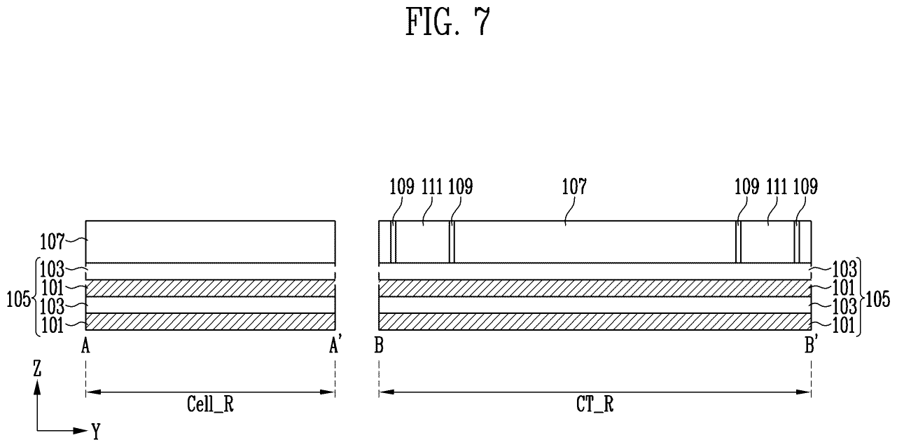

FIGS. 7, 8A, 8B, 9A, 9B, 10A, 10B, 11A, 11B, 12, and 13 are sectional and plan views illustrating a manufacturing method of the semiconductor device in accordance with an embodiment of the present disclosure.

Referring to FIG. 7, a buffer layer 105 may be formed in a cell region Cell_R and a contact region CT_R of the semiconductor device. The buffer layer 105 may be formed by alternately stacking a plurality of first buffer layer 101 and a plurality of second buffer layers 103. For example, the first buffer layer 101 may include a metal material, and the second buffer layer 103 may include rubber or oxide.

Afterwards, a source line layer 107 may be formed on the buffer layer 105. The source line layer 107 may be a doped semiconductor layer. For example, the source line layer 107 may be a semiconductor layer doped with an n-type impurity. In an embodiment, the source line layer 107 may be formed by depositing at least one doped silicon layer on the buffer layer 105.

Afterwards, a region in which a contact pad layer is to be formed may be formed by etching a portion of the source line layer 107 formed on the contact region CT_R. The region in which the contact pad layer is to be formed may be defined as a region electrically connected to the peripheral circuit structure PC, shown in FIGS. 1A and 1B. Then, a contact pad layer 111 may be formed where the portion was removed by etching the source line layer 107. An isolation layer 109 may be formed between the contact pad layer 111 and the source line layer 107, thereby electrically isolating the contact pad layer 111 and the source line layer 107 from each other. The isolation layer 109 may be formed of an insulating layer, e.g., an oxide layer.

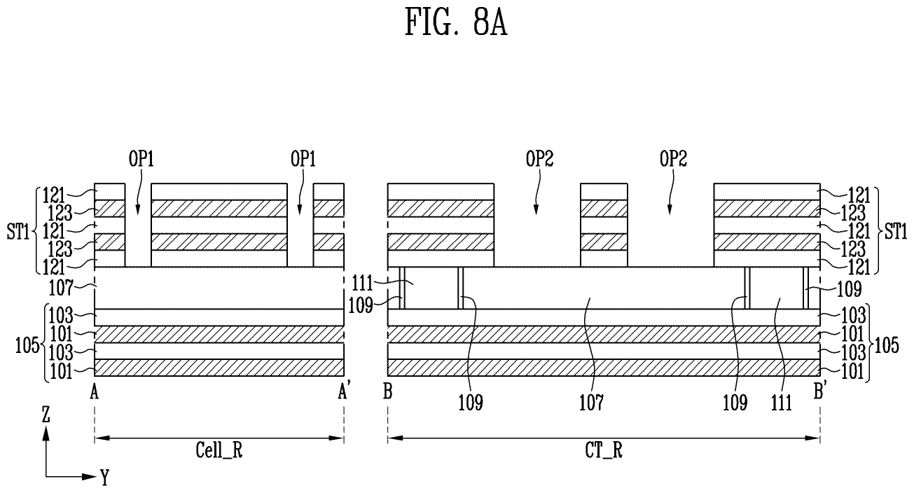

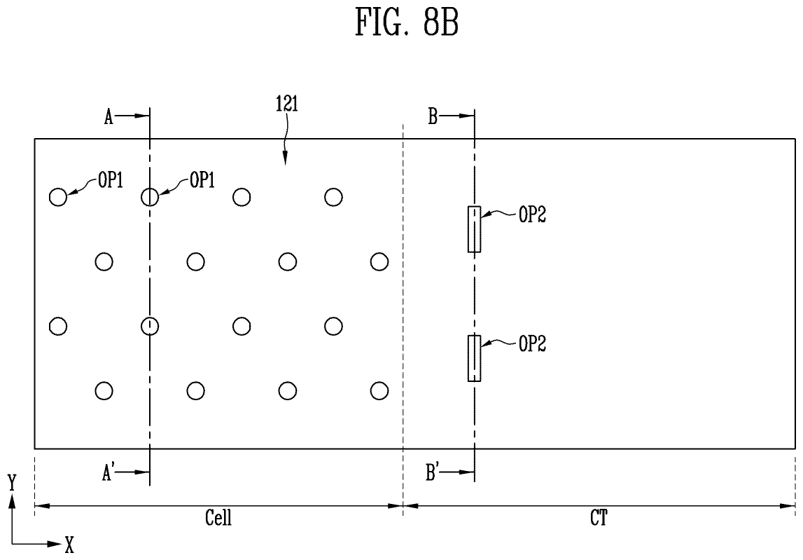

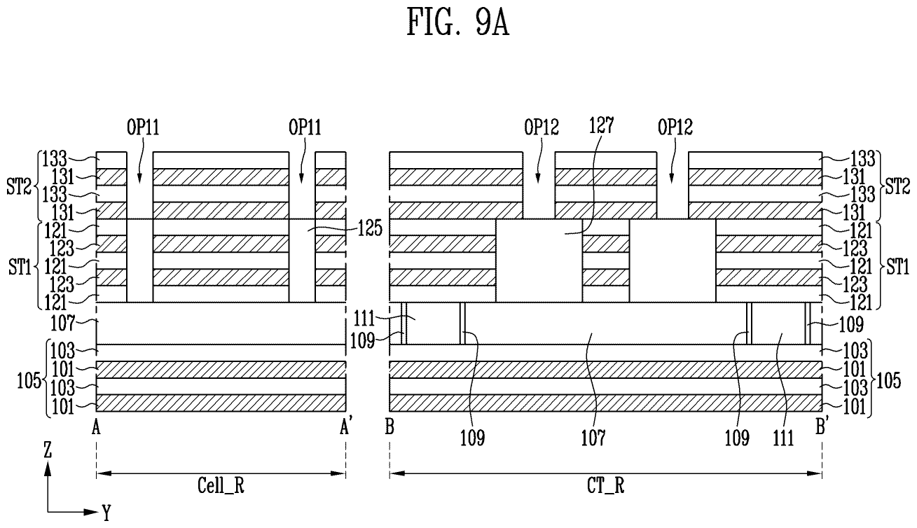

Referring to FIGS. 8A and 8B, a first stack structure ST1 in which first material layers 121 and second material layers 123 are alternately stacked may be formed in the cell region Cell_R and the contact region CT_R. The second material layers 123 may be sacrificial layers for forming conductive layers, such as a word line and a select line, and the first material layers 121 may be used to insulate the stacked conductive layers from each other.

The first material layers 121 may be formed of a material having a high etch selectivity with respect to the second material layers 123. In an example, the first material layers 121 may include an insulating material, such as oxide, and the second material layers 123 may include a sacrificial material, such as nitride.

Afterwards, first openings OP1 penetrating the first stack structure ST1 in the cell region Cell_R and second openings OP2 penetrating the first stack structure on the contact region CT_R may be formed. For example, the first openings OP1 may be formed to have a cross-section of a circle, a hole type, and the second openings OP2 may be formed to have a cross-section of a bar, a bar type, extending in the second horizontal direction Y.

In another embodiment, the second openings OP2 may be formed such that a cross-section thereof has a T shape, a Y shape, or a shape extending in one direction from a circular central portion.

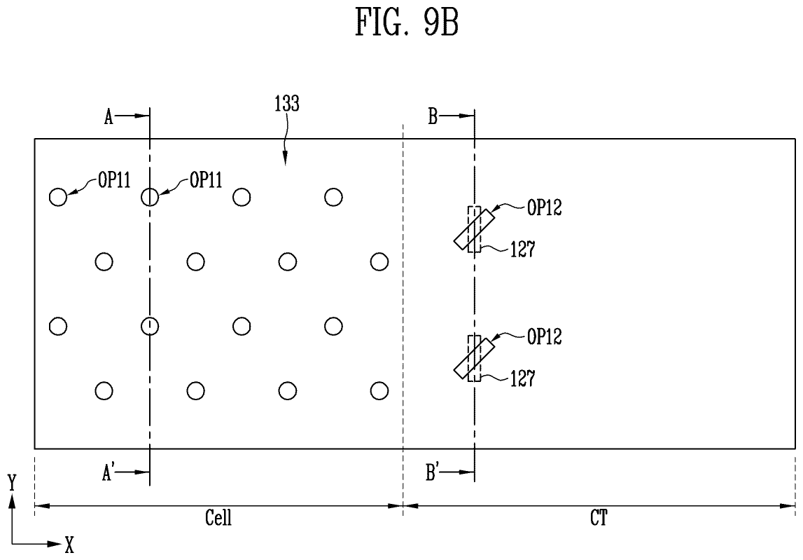

Referring to FIGS. 9A and 9B, a first support structure layer 127 may be formed by filling the second openings (OP2 shown in FIGS. 8A and 8B) with an insulating material. In a process of forming the first support structure layer 127, the first openings (OP1 shown in FIGS. 8A and 8B) may also be filled with the insulating material, thereby forming a first sacrificial pattern 125.

Afterwards, a second stack structure ST2 in which third material layers 131 and fourth material layers 133 are alternately stacked may be formed on the first stack structure ST1 of the cell region Cell_R and the contact region CT_R. The third material layers 131 may be sacrificial layers that form conductive layers, such as a word line and a select line, and the fourth material layers 133 may be used to insulate the stacked conductive layers from each other.

The fourth material layers 133 may be formed of a material having a high etch selectivity with respect to the third material layers 131. In an example, the third material layers 131 may include a sacrificial material, such as nitride, and the fourth material layers 133 may include an insulating material, such as oxide.

Afterwards, first openings OP11 may be formed by exposing the first sacrificial pattern 125 and penetrating the second stack structure ST2 in the cell region Cell_R, and second openings OP12 may be formed by partially overlapping with the first support layer 127 and penetrating the second stack structure ST2 in the contact region CT_R. For example, the first openings OP11 may be formed to have a cross-section of a circle, a hole type, and the second openings OP12 may be formed to have a cross-section of a bar, a bar type, extending in a direction based on the second openings OP12 rotated along the X-Y plane, when assuming that the second openings OP12 is pinned along the Z axis, at a certain angle with respect to an extending direction of the first support structure 127. For example, the second openings OP12 may extend in a first diagonal direction between the first horizontal direction X and the second horizontal direction Y.

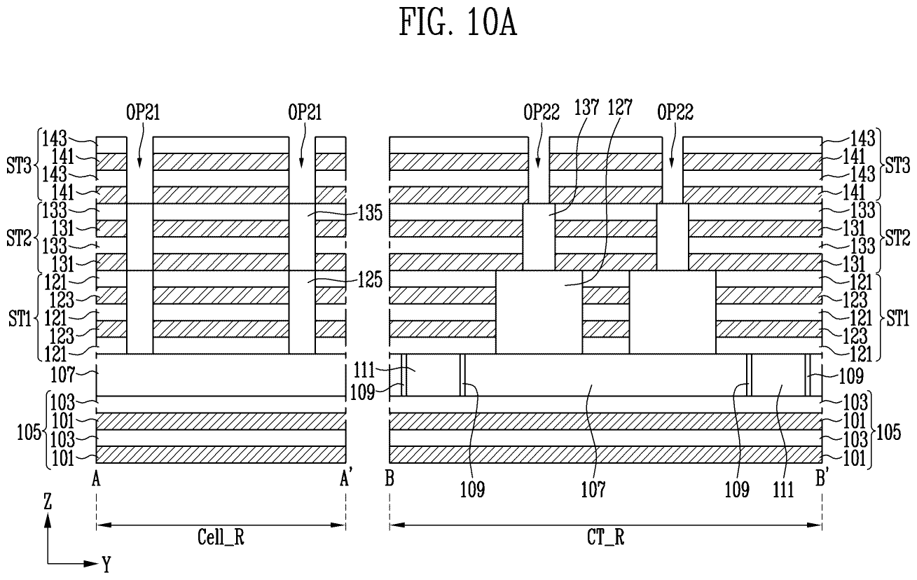

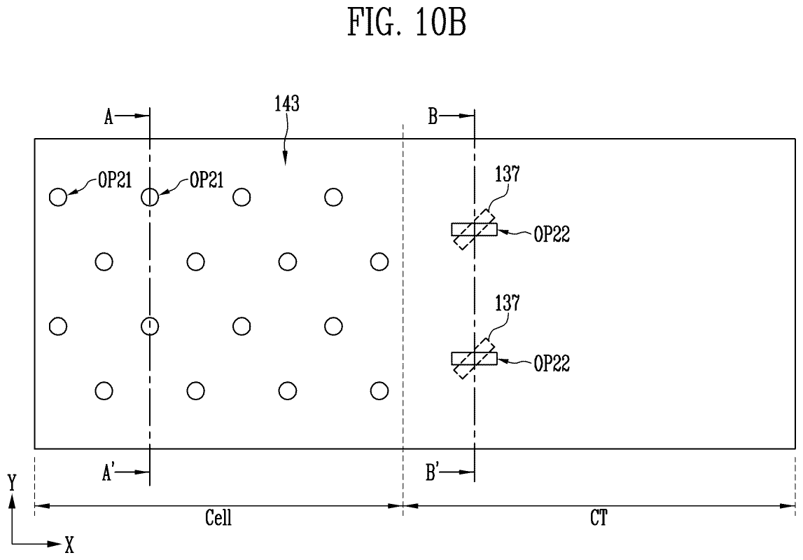

Referring to FIGS. 10A and 10B, a second support structure layer 137 may be formed by filling the second openings (OP12 shown in FIGS. 9A and 9B) with an insulating material. In a process of forming the second support structure layer 137, the first openings (OP11 shown in FIGS. 9A and 9B) may also be filled with the insulating material, thereby forming a second sacrificial pattern 135.

Afterwards, a third stack structure ST3 in which fifth material layers 141 and sixth material layers 143 are alternately stacked may be formed on the second stack structure ST2 of the cell region Cell_R and the contact region CT_R. The fifth material layers 141 may be sacrificial layers for forming conductive layers, such as a word line and a select line, and the sixth material layers 143 may be used to insulate the stacked conductive layers from each other.

The sixth material layers 143 may be formed of a material having a high etch selectivity with respect to the fifth material layers 141. In an example, the fifth material layers 141 may include a sacrificial material, such as nitride, and the sixth material layers 143 may include an insulating material, such as oxide.

Afterwards, first openings OP21 may be formed by exposing the second sacrificial pattern 135 and penetrating the third stack structure ST3 in the cell region Cell_R, and second openings OP22 may be formed by partially overlapping with the second support structure layer 137 and penetrating the third stack structure ST3 in the contact region CT_R. For example, the first openings OP21 may be formed to have a cross-section of a circle, a hole type, and the second openings OP22 may be formed to have a cross-section of a bar, a bar type, extending in a direction based on the second openings OP22 rotated along the X-Y plane, when assuming that the second openings OP22 is pinned along the Z axis, at a certain angle with respect to an extending direction of the second support structure layer 137. For example, the second openings OP22 may extend in the first horizontal direction X.

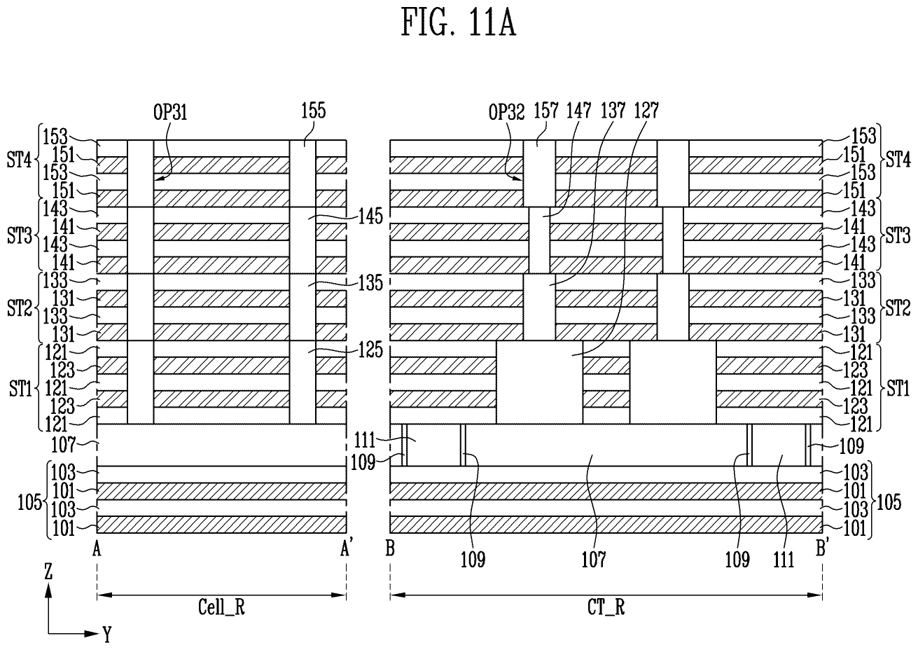

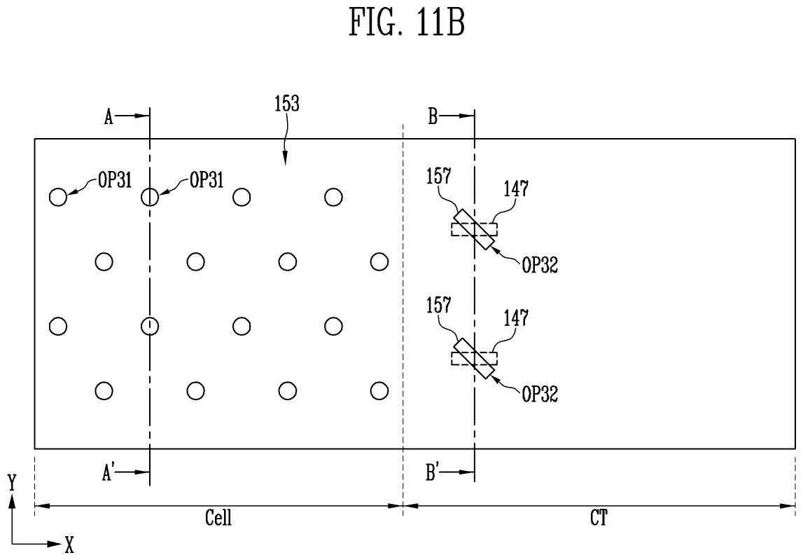

Referring to FIGS. 11A and 11B, a third support structure layer 147 may be formed by filling the second openings (OP22 shown in FIGS. 10A and 10B) with an insulating material. In a process of forming the third support structure layer 147, the first openings (OP21 shown in FIGS. 10A and 10B) may also be filled with the insulating material, thereby forming a third sacrificial pattern 145.

Afterwards, a fourth stack structure ST4 in which seventh material layers 151 and eighth material layers 153 are alternately stacked may be formed on the third stack structure ST3 of the cell region Cell_R and the contact region CT_R. The seventh material layers 151 may be sacrificial layers for forming conductive layers, such as a word line and a select line, and the eighth material layers 153 may be used to insulate the stacked conductive layers from each other.

The eighth material layers 153 may be formed of a material having a high etch selectivity with respect to the seventh material layers 151. In an example, the seventh material layers 151 may include a sacrificial material, such as nitride, and the eighth material layers 153 may include an insulating material, such as oxide.

Afterwards, first openings OP31 may be formed by exposing the third sacrificial pattern 145 and penetrating the fourth stack structure ST4 in the cell region Cell_R, and second openings OP32 may be formed by partially overlapping with the third support structure layer 147 and penetrating the fourth structure ST4 in the contact region CT_R. For example, the first openings OP31 may be formed to have a cross-section of a circle, a hole type, and the second openings OP32 may be formed to have a cross-section of a bar, a bar type, extending in a direction based on the second openings OP32 rotated along the X-Y plane, when assuming that the second openings OP32 is pinned along the Z axis, at a certain angle with respect to an extending direction of the third support structure layer 147. For example, the second openings OP32 may extend in a second diagonal direction between the first horizontal direction X and the second horizontal direction Y.

Afterwards, a fourth support structure layer 157 may be formed by filling the second openings OP32 with an insulating material. In a process of forming the fourth support structure layer 157, the first openings OP31 may also be filled with the insulating material, thereby forming a fourth sacrificial pattern 155.

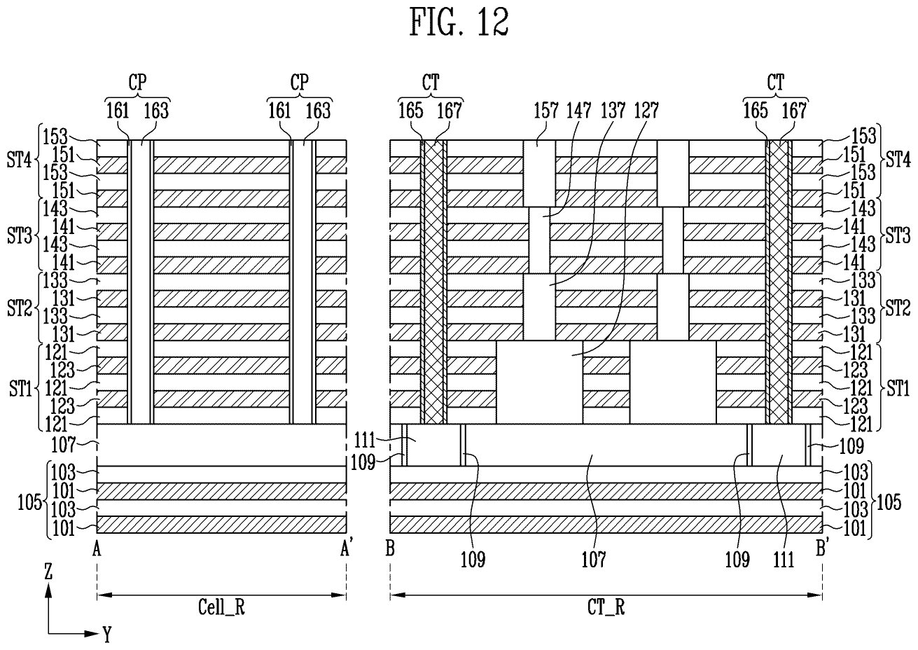

Referring to FIG. 12, channel holes through which the source line layer 107 is exposed may be formed by sequentially removing the fourth sacrificial pattern (155 shown in FIG. 11A), the third sacrificial pattern (145 shown in FIG. 11A), the second sacrificial pattern (135 shown in FIG. 11A), and the first sacrificial pattern (125 shown in FIG. 11A). Afterwards, channel plugs CP, each including a channel layer 163 and a memory layer 161 surrounding the channel layer 163, may be formed in the channel holes. For example, the memory layer 161 may be formed on a sidewall of the channel hole. The memory layer 161 may include at least one of a charge blocking layer, a data storage layer, and a tunnel insulating layer. The data storage layer may include a floating gate, such as silicon, a charge trapping material, such as nitride, a phase change material, a nano dot, and the like. After that, the channel plugs CP may be formed by completely filling the channel hole up to a central region of the channel hole. In another embodiment, the channel layer 163 may be formed in a structure in which the central region of the channel hole is opened, and a gap fill layer may be formed in the opened central region.

Afterwards, contact holes may be formed by sequentially etching the fourth stack structure ST4, the third stack structure ST3, the second stack structure ST2, and the first stack structure ST1 on the contact region CT_R, and contacts CT, each including a contact plug 167 and a barrier layer 165 surrounding the contact plug 167, may be formed in the contact holes. For example, the barrier layer 165 may be formed on a sidewall of the contact hole, and the contact plug 167 may be formed by filling the contact hole with a conductive material.

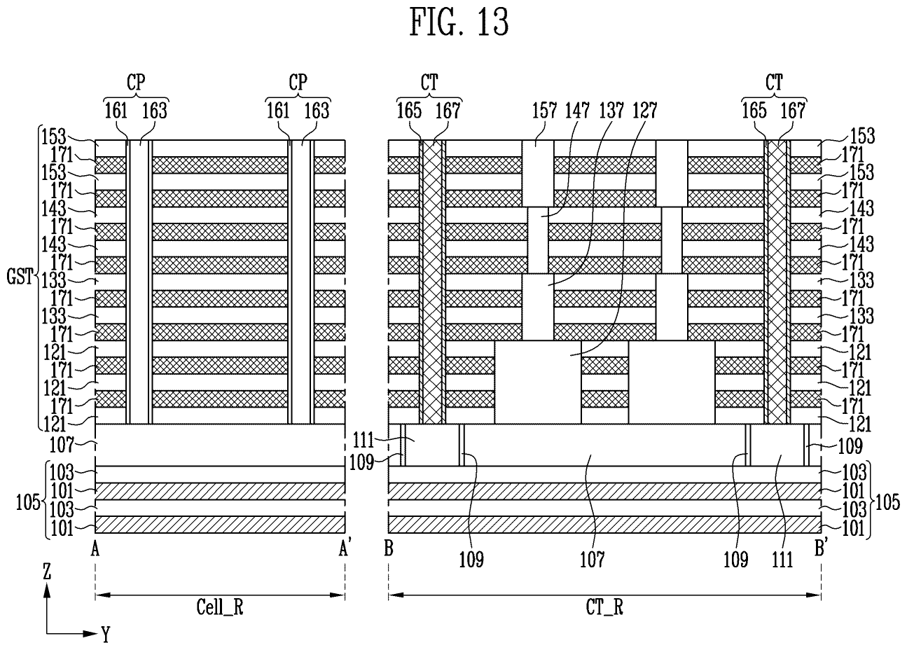

Referring to FIG. 13, a slit may be formed. The slit may penetrate the fourth stack structure (ST4 shown in FIG. 12), the third stack structure (ST3 shown in FIG. 12), the second stack structure (ST2 shown in FIG. 12), and the first stack structure (ST1 shown in FIG. 12), which are formed in the cell region Cell_R and the contact region CT_R. After that, the second material layers (123 shown in FIG. 12), the third material layers (131 shown in FIG. 12), the fifth material layers (141 shown in FIG. 12), and the seventh material layers (151 shown in FIG. 12), which are exposed through the slit, may be removed, and conductive layers 171 may be formed by filling spaces in which the second material layers (123 shown in FIG. 12), the third material layers (131 shown in FIG. 12), the fifth material layers (141 shown in FIG. 12), and the seventh material layers (151 shown in FIG. 12) are removed with a conductive material. The conductive layers 171, the first material layers 121, the fourth material layers 133, the sixth material layers 143, and the eighth material layers 153 may be defined as a gate stack structure GST.

In accordance with the above-described embodiment of the present disclosure, a plurality of support structure layers can be formed, which are stacked on the contact region while being rotated clockwise or counterclockwise.

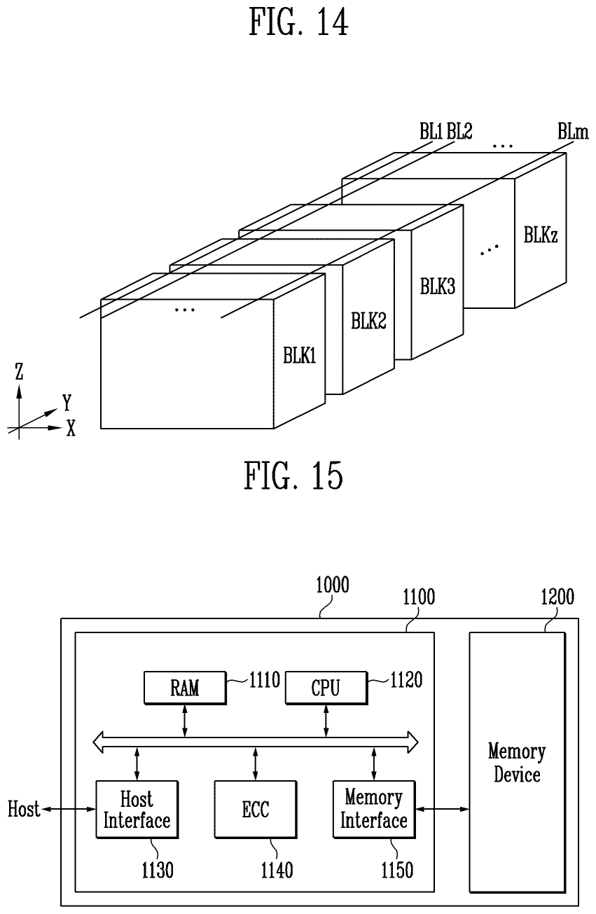

FIG. 14 is a view illustrating memory blocks included in the semiconductor memory device in accordance with an embodiment of the present disclosure.

The semiconductor device may include a plurality of memory blocks BLK1 to BLKz. The plurality of memory blocks BLK1 to BLKz may be arranged to be spaced apart from each other along a direction Y in which bit lines BL1 to BLm extend. For example, first to zth memory blocks BLK1 to BLKz may be arranged to be spaced apart from each other along the second horizontal direction Y and may include a plurality of memory cells stacked along the vertical direction Z. The first to zth memory blocks BLK1 to BLKz may be spaced apart from each other by using slits.

Each of the plurality of memory blocks BLK1 to BLKz may include a plurality of channel plugs, contacts, and a support structure as described above with reference to FIGS. 3A and 3B.

FIG. 15 is a block diagram illustrating a configuration of a memory system in accordance with an embodiment of the present disclosure.

Referring to FIG. 15, the memory system 1000, in accordance with the embodiment of the present disclosure, may include a memory device 1200 and a controller 1100.

The memory device 1200 may be used to store data information having various data forms, such as texts, graphics, and software codes. The memory device 1200 may be the semiconductor device described with reference to FIGS. 1A, 1B, 2, 3A, and 3B and may be manufactured according to the manufacturing method described with reference to FIGS. 7, 8A, 8B, 9A, 9B, 10A, 10B, 11A, 11B, 12, and 13. A structure and a manufacturing method of the memory device 1200 may be the same as described above, and therefore, their detailed descriptions will be omitted.

The controller 1100 may be connected to a host and the memory device 1200 and may be configured to access the memory device 1200 in response to a request from the host. For example, the controller 1100 may be configured to control a read operation, a write operation, an erase operation, a background operation, and the like of the memory device 1200.

The controller 1100 may include a Random Access Memory (RAM) 1110, a Central Processing Unit (CPU) 1120, a host interface 1130, an Error Correction Code (ECC) circuit 1140, a memory interface 1150, and the like.

The RAM 1110 may be used as a working memory of the CPU 1120, a cache memory between the memory device 1200 and the host, a buffer memory between the memory device 1200 and the host, or the like. The RAM 1110 may be replaced with a Static Random Access Memory (SRAM), a Read Only Memory (ROM), or the like.

The CPU 1120 may be configured to control overall operations of the controller 1100. For example, the CPU 1120 may be configured to execute firmware, such as a Flash Translation Layer (FTL) stored in the RAM 1110.

The host interface 1130 may be configured to perform interfacing with the host. For example, the controller 1100 may communicate with the host through at least one of various interface protocols, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer Small Interface (SCSI) protocol, an Enhanced Small Disk Interface (ESDI) protocol, an Integrated Drive Electronics (IDE) protocol, and a private protocol.

The ECC circuit 1140 may be configured to detect an error included in data read from the memory device 1200, using an ECC, and may correct the detected error.

The memory interface 1150 may be configured to perform interfacing with the memory device 1200. For example, the memory interface 1150 may include a NAND interface or a NOR interface.

The controller 1100 may include a buffer memory (not shown) for temporarily storing data. The buffer memory may be used to temporarily store data transferred to an external device through the host interface 1130 or to temporarily store data transferred from the memory device 1200 through the memory interface 1150. Also, the controller 1100 may further include a ROM used to store code data for interfacing with the host.

As such, the memory system 1000, in accordance with the embodiment of the present disclosure, may include the memory device 1200 having an improved degree of integration and an improved characteristic, and thus, the degree of integration and the characteristic of the memory system 1000 can also be improved.

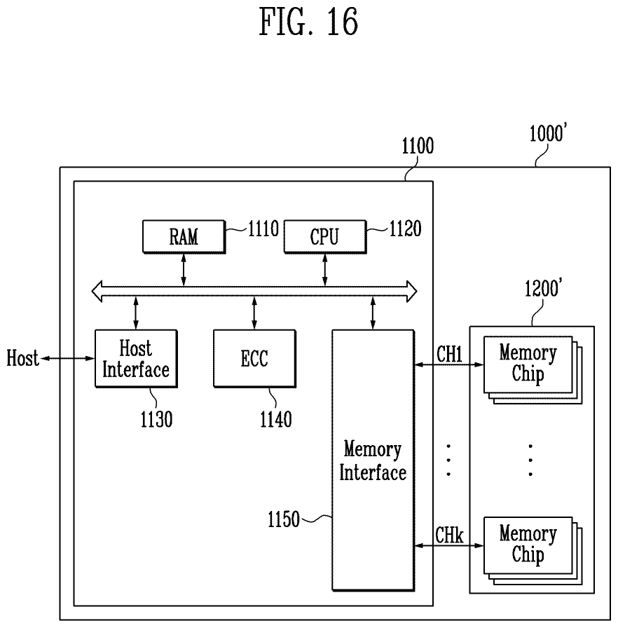

FIG. 16 is a block diagram illustrating a configuration of a memory system in accordance with an embodiment of the present disclosure. Hereinafter, descriptions of portions overlapping with those described above will be omitted.

Referring to FIG. 16, the memory system 1000′, in accordance with the embodiment of the present disclosure, may include a memory device 1200′ and a controller 1100. In addition, the controller 1100 includes a RAM 1110, a CPU 1120, a host interface 1130, an ECC circuit 1140, a memory interface 1150, and the like.

The memory device 1200′ may be a nonvolatile memory. The memory device 1200′ may be the semiconductor device described with reference to FIGS. 1A, 1B, 2, 3A, and 3B and may be manufactured according to the manufacturing method described with reference to FIGS. 7, 8A, 8B, 9A, 9B, 10A, 10B, 11A, 11B, 12, and 13. A structure and a manufacturing method of the memory device 1200′ are the same as described above, and therefore, their detailed descriptions will be omitted.

Also, the memory device 1200′ may be a multi-chip package configured with a plurality of memory chips. The plurality of memory chips may be divided into a plurality of groups, and the plurality of groups may be configured to communicate with the controller 1100 through first to k-th channels CH1 to CHk. In addition, memory chips belonging to one group may be configured to communicate with the controller 1100 through a common channel. The memory system 1000′ may be modified such that one memory chip is connected to one channel.

As such, since the memory system 1000′, in accordance with the embodiment of the present disclosure, includes the memory device 1200′ having an improved degree of integration and improved characteristics, a degree of integration and characteristics of the memory system 1000′ can also be improved. In particular, the memory device 1200′ may be configured as a multi-chip package so that data storage capacity of the memory system 1000′ can be increased and a driving speed can be improved.

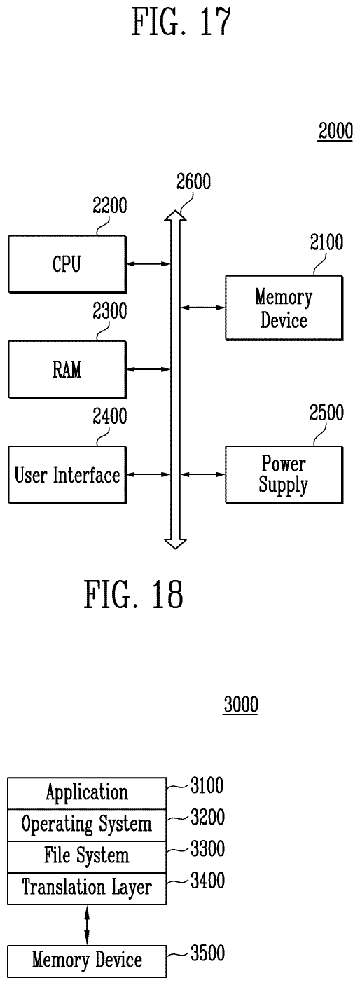

FIG. 17 is a block diagram illustrating a configuration of a computing system in accordance with an embodiment of the present disclosure. Hereinafter, descriptions of portions overlapping with those described above will be omitted.

Referring to FIG. 17, the computing system 2000, in accordance with the embodiment of the present disclosure, may include a memory device 2100, a CPU 2200, a RAM 2300, a user interface 2400, a power supply 2500, a system bus 2600, and the like.

The memory device 2100 may store data provided through the user interface 2400, data processed by the CPU 2200, and the like. Also, the memory device 2100 may be electrically connected to the CPU 2200, the RAM 2300, the user interface 2400, the power supply 2500, and the like through the system bus 2600. For example, the memory device 2100 may be connected to the system bus 2600 through a controller (not shown) or be directly connected to the system bus 2600. When the memory device 2100 is directly connected to the system bus 2600, a function of the controller may be performed by the CPU 2200, the RAM 2300, and the like.

The memory device 2100 may be a nonvolatile memory. The memory device 2100 may be the semiconductor device described with reference to FIGS. 1A, 1B, 2, 3A, and 3B, and be manufactured according to the manufacturing method described with reference to FIGS. 7, 8A, 8B, 9A, 9B, 10A, 10B, 11A, 11B, 12, and 13. A structure and a manufacturing method of the memory device 2100 are the same as described above, and therefore, their detailed descriptions will be omitted.

Also, the memory device 2100 may be a multi-chip package configured with a plurality of memory chips as described with reference to FIG. 16.

The computing system 2000 having such a configuration may be a computer, an ultra-mobile PC (UMPC), a workstation, a net-book, a personal digital assistants (PDA), a portable computer, a web tablet, a wireless phone, a mobile phone, a smart phone, an e-book, a portable multimedia player (PMP), a portable game machine, a navigation device, a black box, a digital camera, a 3-dimensional television, a digital audio recorder, a digital audio player, a digital picture recorder, a digital picture player, a digital video recorder, and a digital video player, a device capable of transmitting and receiving information in a wireless environment, one of various electronic devices configuring a home network, one of various electronic devices configuring a computer network, one of various electronic devices configuring a telematics network, an RFID device, or the like.

As such, since the computing system 2000, in accordance with the embodiment of the present disclosure, includes the memory device 2100 having an improved degree of integration and improved characteristics, characteristics of the computing system 2000 can also be improved.

FIG. 18 is a block diagram illustrating a configuration of a computing system in accordance with an embodiment of the present disclosure.

Referring to FIG. 18, the computing system 3000, in accordance with the embodiment of the present disclosure, may include a software layer including an operating system 3200, an application 3100, a file system 3300, a translation layer 3400, and the like. Also, the computing system 3000 may include a hardware layer, such as a memory device 3500.

The operating system 3200 may be used to manage software, hardware resources, and the like of the computing system 3000 and may be used to manage control program execution of a central processing unit. The application 3100 may be various application programs executed on the computing system 3000 and may be a utility that is executed by the operating system 3200.

The file system 3300 may mean a logical structure for managing data, a file, and the like existing in the computing system 3000. The file system 330 may organize the file or data to be stored in the memory device 3500 according to a rule. The file system 3300 may be determined according to the operating system 3200 used in the computing system 3000. For example, when the operating system 3200 is a Windows system of Microsoft company, the file system 3300 may be a file allocation table (FAT), an NT file system (NTFS), or the like. In addition, when the operating system 3200 is a Unix/Linux system, the file system 3300 may be an extended file system (EXT), a Unix file system (UFS), a journaling file system (JFS), or the like.

Although the operating system 3200, the application 3100, and the file system 3300 are illustrated as separate blocks in this drawing, the application 3100 and the file system 3300 may be included in the operating system 3200.

The translation layer 3400 may translate an address in a form suitable for the memory device 3500 in response to a request from the file system 3300. For example, the translation layer 3400 may translate a logical address generated by the file system 3300 into a physical address of the memory device 3500. Mapping information of the logical address and the physical address may be stored in an address translation table. For example, the translation layer 3400 may be a flash translation layer (FTL), a universal flash storage link layer (ULL), or the like.

The memory device 3500 may be a nonvolatile memory. The memory device 3500 may be the semiconductor device described with reference to FIGS. 1A, 1B, 2, 3A, and 3B and may be manufactured according to the manufacturing method described with reference to FIGS. 7, 8A, 8B, 9A, 9B, 10A, 10B, 11A, 11B, 12, and 13. A structure and a manufacturing method of the memory device 3500 are the same as described above, and therefore, their detailed descriptions will be omitted.

The computing system 3000 having such a configuration may be divided into an operating system layer that is performed in a higher level region and a controller layer that is performed in a lower level region. The application 3100, the operating system 3200, and the file system 3300 may be included in the operating system layer and may be driven by an operation memory of the computing system 3000. In addition, the translation layer 3400 may be included in the operating system layer or in the controller layer.

As such, since the computing system 3000, in accordance with the embodiment of the present disclosure, includes the memory device 3500 having an improved degree of integration and improved characteristics, characteristics of the computing system 3000 can also be improved.

In accordance with the present disclosure, a semiconductor device having a stable structure can be manufactured, and accordingly, characteristics of the semiconductor device can be improved.

While the present disclosure has been shown and described with reference to certain exemplary embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described exemplary embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the exemplary embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A semiconductor device comprising:
a gate stack structure including a plurality of interlayer insulating layers and a plurality of conductive layers, which are alternately stacked in a third direction;
a channel plug formed in a cell region, the channel plug penetrating the gate stack structure in the third direction; and
at least one support structure formed in a contact region, the at least one support structure penetrating the gate stack structure in the third direction,
wherein the support structure includes a plurality of support structure layers that are sequentially stacked in the third direction, and
wherein the plurality of support structure layers are sequentially disposed such that each of the plurality of support structure layers extends in different directions along a plane defined by a first direction and a second direction, and
wherein the first direction, the second direction, and the third direction are orthogonal to each other.

2. The semiconductor device of claim 1, wherein the support structure has a screw shape, a twist shape, or a spiral step shape, and
wherein the plurality of support structure layers forms a plurality of radial lines extending in different directions through a common center.

3. The semiconductor device of claim 1, wherein each of the plurality of support structure layers has a bar shape.

4. The semiconductor device of claim 3, wherein each of the plurality of support structure layers extends in a direction along the plane defined by the first direction and the second direction, rotated at a certain angle clockwise or counterclockwise with respect to an extending direction of an upper support structure layer or a lower support structure layer.

5. The semiconductor device of claim 3, wherein each of the plurality of support structure layers includes a body portion having the bar shape and a protrusion portion extending in one direction from a central portion of the body portion.

6. The semiconductor device of claim 1, wherein each of the plurality of support structure layers includes:
a body portion having a cylindrical structure; and
a protrusion portion extending in one direction from the body portion.

7. The semiconductor device of claim 6, wherein the body portions of the plurality of support structure layers are disposed to overlap with each other in the third direction, and
wherein the protrusion portions of the plurality of support structure layers are disposed to protrude in different directions.

8. The semiconductor device of claim 1, further comprising a buffer layer disposed under the gate stack structure.

9. The semiconductor device of claim 8, wherein the buffer layer includes at least one first buffer layer and at least one second buffer layer, and
wherein the at least one first buffer layer and the at least one second buffer layer are alternately stacked.

10. The semiconductor device of claim 9, wherein the at least one first buffer layer includes a metal material, and
wherein the at least one second buffer layer includes rubber or oxide.

11. A semiconductor device comprising:
a buffer layer, extending in a plane defined by a first direction and a second direction, including a plurality of first buffer layers and a plurality of second buffer layers, which are alternately stacked in a third direction;
a gate stack structure including a plurality of interlayer insulating layers and a plurality of conductive layers, which are alternately stacked on the buffer layer; and
a channel plug formed in a cell region and penetrating the gate stack structure in the third direction,
wherein the first direction, the second direction, and the third direction are orthogonal to each other.

12. The semiconductor device of claim 11, wherein the plurality of first buffer layers includes a metal material, and
wherein the plurality of second buffer layers includes rubber or oxide.

13. The semiconductor device of claim 11, further comprising at least one support structure formed on a contact region and penetrating the gate stack structure in the third direction.

14. The semiconductor device of claim 13, wherein the at least one support structure has a screw shape, a twist shape, or a spiral step shape,
wherein the at least one support structure includes a plurality of support structure layers, the plurality of support structure layers forming a plurality of radial lines extending in different directions through a common center.

15. The semiconductor device of claim 13, wherein the at least one support structure includes a plurality of support structure layers that are sequentially stacked in a third direction, and
wherein the plurality of support structure layers are sequentially disposed such that each of the plurality of support structure layers extends in different directions along the plane defined by the first direction and the second direction.

16. The semiconductor device of claim 15, wherein each of the plurality of support structure layers has a bar shape.

17. The semiconductor device of claim 16, wherein each of the plurality of support structure layers extends in a direction along the plane defined by the first direction and the second direction, rotated at a certain angle clockwise or counterclockwise with respect to an extending direction of an upper support structure layer or a lower support structure layer.

18. The semiconductor device of claim 16, wherein each of the plurality of support structure layers includes a body portion having the bar shape and a protrusion portion extending in one direction from a central portion of the body portion.

19. The semiconductor device of claim 15, wherein each of the plurality of support structure layers includes:
a body portion having a cylindrical structure; and
a protrusion portion extending in one direction from the body portion.

20. The semiconductor device of claim 19, wherein the body portions of the plurality of support structure layers are disposed to overlap with each other in the third direction, and
wherein the protrusion portions of the plurality of support structure layers are disposed to protrude in different directions.

21. A method of manufacturing a semiconductor device, the method comprising:
forming a first stack structure, extending in a plane defined by a first direction and a second direction, in which a plurality of first interlayer insulating layers and a plurality of first sacrificial layers are alternately stacked in a third direction on a substrate, the first stack structure including a cell region and a contact region, wherein the first direction, the second direction, and the third direction are orthogonal to each other;
forming a first support structure penetrating the first stack structure on the contact region, wherein the first support structure is formed to extend in the first direction;
forming, on the first stack structure, a second stack structure in which a plurality of second interlayer insulating layers and a plurality of second sacrificial layers are alternately stacked;
forming a second support structure in the contact region, the second support structure having a portion overlapping with the first support structure and penetrating the second stack structure, wherein the second support structure is formed to extend in a direction that is rotated at a certain angle with respect to the first direction;
forming, on the second stack structure, a third stack structure in which a plurality of third interlayer insulating layers and a plurality of third sacrificial layers are alternately stacked; and
forming a third support structure in the contact region, the third support structure having a portion overlapping with the second support structure and penetrating the third stack structure, wherein the third support structure is formed to extend in a direction that is rotated at a certain angle with respect to the extending direction of the second support structure.

22. The method of claim 21, wherein each of the first support structure, the second support structure, and the third support structure is formed in a bar shape.

23. The method of claim 21, further comprising forming a buffer layer by alternately stacking a plurality of first buffer layers and a plurality of second buffer layers on the substrate before the first stack structure is formed.

24. The method of claim 23, wherein the plurality of first buffer layers includes a metal material, and
wherein the plurality of second buffer layers includes rubber or oxide.

25. The method of claim 21, wherein, in the forming of the first support structure, a first sacrificial pattern penetrating the first stack structure that is formed in the cell region is formed,
wherein, in the forming of the second support structure, a second sacrificial pattern in contact with the first sacrificial pattern and penetrating the second stack structure that is formed in the cell region is formed, and
wherein, in the forming of the third support structure, a third sacrificial pattern in contact with the second sacrificial pattern and penetrating the third stack structure that is formed in the cell region is formed.

26. The method of claim 25, further comprising:
forming a channel hole by removing the first sacrificial pattern, the second sacrificial pattern, and the third sacrificial pattern; and
forming a channel plug in the channel hole.

27. The method of claim 21, further comprising:
exposing sidewalls of the first sacrificial layer, the second sacrificial layer, and the third sacrificial layer by etching the first stack structure, the second stack structure, and the third stack structure to be penetrated; and
forming a plurality of conductive layers by removing the first sacrificial layer, the second sacrificial layer, and the third sacrificial layer and filling, with a conductive material, spaces in which the first sacrificial layer, the second sacrificial layer, and the third sacrificial layer are removed.
